(19) United States
(12) Patent Application Publication
(10) Pub. No.: US 2017/0145564 A1
(43) Pub. Date: May 25, 2017

(54) VAPOR DELIVERY SYSTEM

(71) Applicant: Ultratech, Inc., San Jose, CA (US)

(72) Inventors: Adam Bertuch, Boston, MA (US); Michael Ruffo, Medford, MA (US)

(73) Assignee: Ultratech, Inc., San Jose, CA (US)

(21) Appl. No.: 15/113,659

(22) PCT Filed: Jan. 22, 2015
(86) PCT No.: PCT/US2015/012476

§ 371 Date: Jul. 22, 2016

Related U.S. Application Data
(60) Provisional application No. 61/930,870, filed on Jan. 23, 2014.

(51) Int. Cl. C23C 16/455; C23C 16/448; C23C 16/52

(52) U.S. Cl. CPC C23C 16/45544; C23C 16/52; C23C 16/4482; C23C 16/45557

(57) ABSTRACT

An improved ALD system usable for low vapor pressure liquid and sold precursors. The ALD system includes a precursor container and inert gas delivery elements configured to increase precursor vapor pressure within a precursor container by injecting an inert gas pulse into the precursor container while a precursor pulse is being removed to the reaction chamber. A controllable inert gas flow valve and a flow restrictor are disposed along an inert gas input line leading into the precursor container below its fill level. A vapor space is provided above the fill level. An ALD pulse valve is disposed along a precursor vapor line extending between the vapor space and the reaction chamber. Both valves are pulsed simultaneously to synchronously remove precursor vapor from the vapor space and inject inert gas into the precursor container below the fill level.

### CROSS REFERENCE TO RELATED U.S. PATENT APPLICATIONS

The present application claims priority under 35 U.S.C. §119(e) to provisional U.S. Patent Application Ser. No. 61/903,807 (Docket No. 3521.390) filed Jan. 23, 2013, which is incorporated herein by reference in its entirety and for all purposes.

### COPYRIGHT NOTICE

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, however otherwise reserves all copyright rights whatsoever. The following notice shall apply to this document: Copyright 2015 Ultratech Inc.

### BACKGROUND OF THE INVENTION

a. Field of the Invention

The present invention relates to a vapor deliver system operable to deliver precursor or reactant vapor pulses into a reaction chamber. In particular the invention replaces a conventional Mass Flow Controller (MFC) with a pulse valve.

b. The Related Art

It is a typical problem in gas and or vapor phase depositions systems that vapor phase materials gleaned from liquid and solid precursor materials have a low vapor pressure, e.g. at room temperature or higher temperatures, which in some cases has prevented the use of some otherwise desirable low vapor pressure liquid or solid precursor materials. One prior art solution used to increase the vapor pressure of low vapor pressure liquid and solid precursor materials is to heat the liquid or solid precursor material to a temperature that increases its vapor pressure to usable levels for vapor deposition cycles. While heating liquid and or solid precursor materials to provide a suitable vapor pressure for vapor deposition cycles is effective for some low vapor pressure precursor materials, there are upper temperature limits above which the precursor vapor is no longer suitable for vapor deposition cycles. In particular most precursor vapor phase materials gleaned from liquid and or solid precursor materials have a breakdown temperature above which the precursor vapor is rendered ineffective or less effective for the desired gas deposition reaction. In the specific example where vapor phase precursors are used in an Atomic Layer Deposition (ALD) reaction chamber, the breakdown temperatures of many desirable vapor phase precursor materials is between 75 and 150° C. such that any heating steps that heat the vapor phase precursor materials above 150° C. is not a viable solution for increasing precursor vapor pressure for ALD deposition cycles.

A further prior art solution is to provide flow of an inert gas through a bubbler to bubble the inert gas through liquid or solid precursor material contained within a container. In this case the container is substantially sealed expect that an inert gas can be injected into the container and precursor vapor can be removed from the container using controllable valves or the like. Specifically the container is partially filled with a low vapor pressure liquid or solid precursor and a vapor space is present inside the container above the level of the liquid or solid precursor housed therein. A gas bubbler includes a gas input line provided to inject a flow of inert gas into the otherwise sealed precursor container and the gas input line is disposed to release the inert gas therefrom below the level of precursor in the container. As a result, inert gas bubbles up through the liquid or solid precursor material to the vapor space above the level of precursor in the container.

The bubbler provides two benefits which are: to percolate through or evaporate liquid or solid precursor material to collect or entrain precursor vapor in a vapor space above the level of precursor in the sealed container and; to increase the overall gas pressure in the container. In particular the increase in overall pressure also increases the partial precursor vapor pressure in the vapor space above the level of liquid or solid precursor contained within the sealed container.

In many prior art bubbler systems a continuous flow of inert gas flows into the precursor container and a continuous flow of vapor phase precursor material flows out of the precursor container and the vapor phase precursor material is either delivered into a reaction chamber to react with a solid material surface supported therein or the precursor vapor is vented out of the system. In continuous flow bubbler systems there is no need to stop the flow of inert gas being input to the precursor container and the only control on the output is to modulate the mass flow rate and either direct the precursor vapor into the reaction chamber or to divert the precursor vapor to be vented out of the system. For example continuous flow bubbler systems are usable in some Chemical Vapor Deposition (CVD) systems because CVD cycles are compatible with delivering a continuous flow of precursor vapor into the reaction chamber during a CVD coating cycle. However this is not the case for ALD coating cycles.

As a result continuous flow bubbler systems are not suitable for ALD systems. Instead additional gas flow control elements are needed to start and stop precursor vapor material delivery to the reaction chamber and to manage total gas pressure inside the precursor container especially when precursor vapor is not being removed from the precursor container. In addition, instead of venting unused precursor vapor material out of the system, it is desirable to conserve precursor vapor material, to reduce operating cost, and to eliminate the cost of disposing of or otherwise neutralizing potentially harmful and or volatile precursor vapor materials when they are merely vented outside the system.

For conventional ALD systems, each precursor vapor is pulsed to the reaction chamber by a separate ALD pulse valve. ALD pulse valves are disposed between sealed precursor containers and the reaction chamber and may be incorporated within a gas input manifold usable to control precursor input to the reaction chamber. For each pulse valve, a pulse duration and a partial vapor pressure inside the sealed precursor container at the time that the pulse valve is opened or pulsed are generally proportional to the volume of precursor that is released into the reaction chamber during each precursor pulse. In particular, precursor pulse valves usually have pulse durations in the range of 1-100 msec with a pulse to pulse frequency of about three to four times the pulse duration.

Continuous flow bubbler systems receive inert gas from a gas supply module and are interfaced with a precursor container to substantially continuously pass inert gas flow through the precursor container. An inert gas such as nitrogen is provided to a feed tube from a pressurized gas container, or the like, at a substantially regulated gas pressure, e.g. between about 10 and 70 pounds per square inch (PSI). The mass flow rate of inert gas entering into the precursor container is generally modulated to a relatively low mass flow rate by a mass flow controller (MFC) disposed between the pressure regulator and the sealed precursor container. Typically a steady mass flow rate of inert gas is injected into the precursor container and a steady mass flow rate of precursor vapor is released from the container to a reaction chamber or vented out of the system.

An example non-continuous flow bubbler system for an ALD gas delivery system that delivers pulses of inert gas into the precursor container is described in related U.S. patent application Ser. No. 13/162,850 to Liu et al. entitled Method And Apparatus For Precursor Delivery filed on Jun. 17, 2011 and published as US20110311726. Liu et al. discloses a pulse valve disposed along an inert gas input conduit between a pressure regulator and a sealed precursor container and further discloses an orifice for restricting inert gas flow to the precursor container. The orifice is disposed along the input gas conduit between the pressure regular and the pulse valve. The flow restrictor replaces a convention Mass Flow Controller (MFC) to limit gas flow when the pulse valve is opened to inject inert gas into the precursor container. However Liu et al. disclose that the input conduit does not deliver the input gas pulses being injected into the sealed container below the level of precursor contained therein, but instead delivers input inert gas into the vapor space above the level of liquid and solid precursor contained within the precursor container. One problem with this prior art configuration is that the inert gas pulse entering the precursor container fails to percolate through or evaporate the precursor material to collect or entrain precursor material. Additionally, Liu et al. disclose a system that uses two pulse valves to generate a desirable input pulse which increases cost. Moreover traditional prior art bubbler systems required operational safety features such as a bypass line disposed between the input side of the precursor container and a vacuum pump or an exhaust vent to purge excess input gas including any vapor phase precursor materials contained within in the sealed precursor container when a total gas pressure inside the sealed container exceeds a safe operating pressure. Moreover the vapor phase precursor material can be hazardous, flammable or both and therefore needs to be vented to a safe area. While this safety feature is beneficial it adds complexity and cost.

### BRIEF SUMMARY OF THE INVENTION

In contras to the problems associated with prior art continuous and non-continuous gas flow bubbler systems described above the present invention provides an improved ALD system that includes an improved precursor delivery system and method. The ALD system of the present invention includes a reaction chamber connected to a vacuum pump. The vacuum pump runs continuously to remove gas from the reaction chamber e.g. to precursors present in the reaction chamber reacting with solid substrate surfaces and to remove inert gas delivered into the reaction chamber to flush the reaction chamber of reaction by product and or unreacted precursor. The ALD system of the present invention also includes a precursor container containing either a liquid or solid precursor material filled to a fill level to provide a vapor space above the fill level. The present invention precursor container includes heating elements to heat the precursor to increase vapor pressure without heating the precursor above a precursor breakdown temperature. An inert gas input line is provided to receive inert gas from an inert gas source and deliver the inert gas into the precursor container below the fill level. A precursor vapor line is disposed between the precursor vapor space and the reaction chamber. A controllable ALD pulse valve is disposed along the precursor vapor line between the precursor vapor space and the reaction chamber. A controllable inert gas flow valve is disposed along the inert gas input line between the precursor container and the inert gas source. Both valves are initially closed and when both valves are closed the precursor container is substantially sealed and isolated from the reaction chamber and the inert gas source.

A system controller in electrical communication with each of the controllable ALD pulse valve and the controllable inert gas flow valve is operable to pulse each of the controllable ALD pulse valve and the controllable inert gas flow valve. Each pulse includes opening the valve for a pulse duration ranging from 1 to 100 msec. While the ALD pulse valve is open precursor vapor flows out of the vapor space, through the ALD pulse valve and into the reaction chamber. While the controllable inert gas flow valve is open inert gas in the inert gas input line flows through the controllable inert gas flow valve and into the precursor container and is emitted below the fill level such that the inert gas bubbles up through the liquid or solid precursor to the vapor space provided above the fill line. The bubbling provides two benefits: to percolate through or evaporate the liquid or solid precursor material to collect or entrain precursor vapor in a vapor space above the fill level; and to increase the overall gas pressure in the container. The increase in overall pressure also increases the partial precursor vapor pressure in the vapor space.

These and other aspects and advantages will become apparent when the Description below is read in conjunction with the accompanying Drawings.

### BRIEF DESCRIPTION OF THE DRAWINGS

The features of the present invention will best be understood from the detailed description of the invention and example embodiments thereof selected for the purposes of illustration and shown in the accompanying drawings in which:

FIG. 1 depicts an exemplary schematic diagram of an Atomic Layer Deposition system of the present invention configured with an improved precursor vaporization system.

FIG. 2 depicts an exemplary plot of gas pressure in Torr at a plurality of locations in an Atomic Layer Deposition system according to the present invention.

FIG. 3 depicts an exemplary plot of gas flow rate in standard cubic centimeters per minute (sccm) vs gas pressure in pounds per square inch gauge (psig) for a plurality of different orifice diameters used for gas flow restrictor according to the present invention.

### DESCRIPTION OF THE INVENTION

### Exemplary System Architecture

The present invention provides a simple and effective method to integrate a bubbled/flow-through low vapor pressure delivery (LVPD) system for Atomic Layer Deposition (ALD) systems. The hardware design eliminates the need for an MFC and a switching flow valve for redirecting the flow of the carrier gas with use of manual purge valves to allow safe purging of the precursor delivery lines which can be used for both solid and liquid precursor materials.

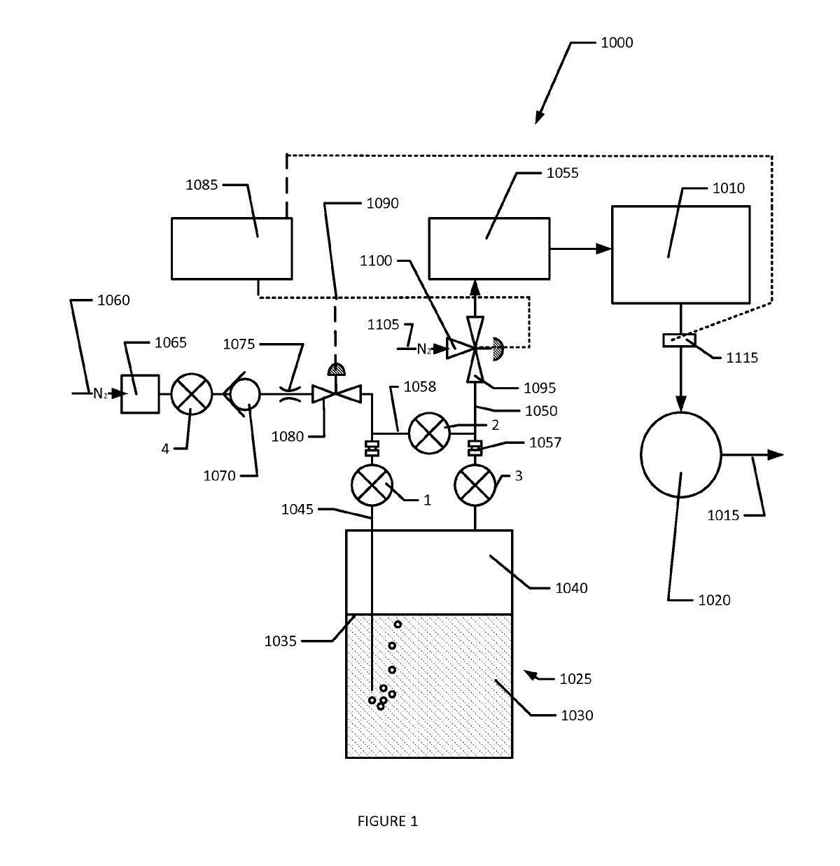

Referring now to FIG. 1 a non-limiting exemplary ALD system (1000) of the present invention is shown schematically. The ALD system (1000) includes a reaction chamber (1010) vented to an exhaust vent (1015) through a vacuum pump (1020). A single precursor container (1025) includes a liquid or solid precursor material (1030) filled to a fill level (1035) with a vapor space (1040) provided above the fill level (1035). Valves (1) (2) and (3) are manually operated valves. Valve (1) is disposed on an inert gas input line (1045) leading into the precursor container (1025) having an end below the fill line (1035). Valve (3) is connected between the vapor space (1040) of single percursor container (1025) disposed on a precursor vapor delivery line (1050) via gas line fitting (1057) leading from single precursor container (1025) finally to the reaction chamber (1010). While a single precursor container (1025) is shown here, an ALD manifold (1055) is provided to receive precursor vapor from a plurality of different precursor containers (1025), and deliver a precursor vapor from one or more selected precursor containers (1025) into the reaction chamber (1010) as required to perform ALD coating cycles. Valve (2) is disposed along a precursor container bypass line (1058). The bypass line (1058) connects the inert gas input line (1045) to the precursor vapor delivery line (1050).

The manual valves (1) and (3) are attached to the precursor container (1025) and are provided to manually close the inert gas input line (1045) and the precursor vapor delivery line (1050) so the precursor container can be removed from the ALD system, e.g. to be exchanged for another precursor container or refilled and replaced, or to otherwise isolate the precursor container from the ALD system (1000). Preferably, each of the inert gas input line (1045) and the precursor vapor delivery line (1050) includes a quick connect gas line fitting (1057), or the like, provided to detach and reattach the precursor container (1025) to the ALD system at the quick connect line fitting (1057).

A supply of nitrogen gas or other inert gas (1060) is delivered into the inert gas input line (1045) from a gas supply module, not shown. The input gas pressure may be between 10 and 70 pounds per square inch (PSI). A gas pressure regulator (1065) is optionally disposed along the inert gas input line (1045) to regulate inert gas input pressure to a desired range. In the present non-limiting example embodiment, the desired input gas pressure as maintained by the gas pressure regulator (1065) is 40 PSI. Optionally a manual valve (4) is disposed along the inert gas input line (1045) between the gas supply module and the manual valve (1) to close the inert gas input line (1045) when no precursor container (1025) is installed and to block inert gas flow as needed.

A check valve (1070) is optionally disposed along the inert gas input line (1045) between the gas supply module and the precursor container (1025). The check valve (1070) allows gas flow in one direction only, which in the present example is from the gas supply module toward the precursor container (1025). The check valve (1070) is included as a safety feature to prevent precursor vapor flowing out of the vapor space (1040) to the manual valve (4) where it can be inadvertently released to atmosphere.

A flow restrictor (1075) is disposed along the inert gas input line (1045) between the pressure regulator (1065) and the precursor container (1025). The flow restrictor locally reduces the area of a gas conduit formed by the inert gas input line (1045) to restrict the volume or mass flow rate of gas that can passes through the flow restrictor as compared with the volume or mass flow rate of gas passing through the gas conduit without restriction.

In the present non-limiting example embodiment the flow restrictor (1075) comprises an orifice disposed along the inert gas input line (1045). The orifice may be circular, oval, square or any other shape. Alternately, the flow restrictor (1075) may comprise any element that reduces the flow area of the conduit formed by the inert gas input line (1045), such as a screen mesh, a crimp formed in outer walls of the inert gas input line (1045) a porous material disposed in the flow path, or the like.

A controllable inert gas flow valve (1080) is disposed along the inert gas input line (1045) between the precursor container (1025) and the flow restrictor (1075). The controllable inert gas flow valve (1080) is operable to open and close in response to an electronic signal generated by a system controller (1085). A communication channel (1090) connects the controllable inert gas flow valve (1080) with the system controller (1085) to exchange electrical communication signals there between. The controllable inert gas flow valve (1080) provides a gas flow conduit passing there through along the axis of the inert gas input line (1045) such that when the controllable inert gas flow valve is open inert gas passes through the controllable inert gas flow valve to the precursor container (1025). The controllable inert gas flow valve (1080) includes a solenoid actuated movable gate, not shown, that is movable to block gas flow through the controllable inert gas flow valve (1080) to thereby prevent gas flow through the inert gas input line (1045) when the solenoid actuated gate is in a closed position.

The controllable inert gas flow valve (1080) operates as a pulse valve. The solenoid actuated gate is initially in the closed position by default, e.g. spring loaded to remain closed. The solenoid actuated gate of the controllable inert gas flow valve (1080) is moved to an open position in response to a pulse command received from the system controller (1085). The pulse command causes the solenoid actuated gate to briefly move to the open position and then rapidly return to the closed position, e.g. being returned by a spring force. The pulse duration is defined as the temporal period during which solenoid actuated movable gate is open, e.g. extending from when the movable gate begins to move towards a fully open position until the movable gate returns to its closed position. In the present non-limiting example embodiment the controllable inert gas flow valve (1080) is configured for a pulse duration range of 1 to 100 msec.

During the pulse duration a volume of inert gas flows through the controllable inert gas flow valve (1080) and enters the precursor container (1025) through the inert gas input line (1045). The volume of inert gas that passes through the controllable inert gas flow valve (1080) during each pulse duration is called the “pulse volume.” The pulse volume depends in part on; the setting of the pressure regulator (1065) or more generally inert gas input pressure, the gas flow area of the flow restrictor (1075), the pulse duration and the total gas pressure inside the precursor container (1025).

In one non-limiting operating mode one or both of the controllable inert gas flow valve (1080) and the system controller (1085) are operable to vary pulse duration as a means of varying pulse volume as needed to optimize inert gas delivery into the precursor container (1025) to increase precursor vapor pressure. In various example embodiments, the pulse duration can be varied by mechanically adjusting an element of the controllable inert gas flow valve (1080), e.g. during a calibration step. In this example embodiment, the pulse duration of the controllable inert gas flow valve (1080) is adjusted once or periodically to optimize performance. Alternately, the pulse duration can be varied by varying the pulse command generated by the system controller (1085). In this example embodiment, pulse duration can be varied electronically to selectively vary pulse duration to increase or decrease pulse volume for different precursor materials and or for deposition cycle types. In one non-limiting example embodiment, the pulse command used to cause the solenoid actuated gate to open is altered to open the solenoid actuated gate for longer or shorter pulse durations as a means to increase or decrease pulse volume.

In another non-limiting operating mode example, the pulse volume of the controllable inert gas flow valve (1080) can be altered by varying the input gas pressure such as by manually or electronically adjusting an operating point of the gas pressure regulator (1065). In another non-limiting operating mode example, the gas flow area of the flow restrictor (1075) can be varied to alter pulse volume either by manually or electronically exchanging the gas flow restrictor (1075) for a different orifice size or by manually or electronically varying the gas flow area by movement of a mechanical elements e.g. where a mechanical element is moved to increase or decrease a gas flow area such as may be the case when the flow restrictor (1075) is an adjustable needle valve or the like. In another non-limiting operating mode example, each pulse volume is substantially equal, however the system controller (1085) is operated to pulse the controllable inert gas flow valve (1080) a plurality of times as a means to increase the overall volume of inert gas being delivered to the precursor container (1025).

An ALD pulse valve (1095) is disposed along the precursor vapor delivery line (1050) between the precursor container (1025) and the reaction chamber (1010). The ALD pulse valve (1095) is operable to open and close in response to an electronic signal generated by the system controller (1085). The communication channel (1090) connects the ALD pulse valve (1095) with the system controller (1085) to exchange electrical communication signals there between. The ALD pulse valve (1095) provides a gas flow conduit passing there through along the axis of the precursor vapor delivery line (1050) such that when the ALD pulse valve (1095) is open, precursor vapor passes through the ALD pulse valve (1095) to the reaction chamber (1010) after passing through the ALD manifold (1055).

The ALD pulse valve (1095) includes a solenoid actuated movable gate, not shown. The solenoid actuated movable gate is movable to block gas flow through the ALD pulse valve (1095) to thereby prevent precursor vapor to flow through the precursor vapor delivery line (1050) when the solenoid actuated movable gate of the ALD pulse valve (1095) is in a closed position. The solenoid actuated movable gate of the ALD pulse valve (1095) is initially in a closed position by default, e.g. the movable gate is spring loaded to remain closed. The solenoid actuated movable gate of the ALD pulse valve (1095) is moved to an open position in response to an ALD pulse command received from the system controller (1085). The ALD pulse command causes the solenoid actuated movable gate of the ALD pulse valve (1095) to briefly move to an open position and the spring load causes the movable gate to rapidly return to its closed position. The ALD pulse duration is the temporal period during which the movable gate of the ALD pulse valve (1095) is open. The ALD pulse duration extends from when the movable gate begins to move from its closed position toward a fully open position, until the movable gate returns to its closed position. In the present non-limiting example embodiment the ALD pulse valve (1095) is configured for a pulse duration range of 1 to 100 msec.

The ALD pulse valve (1095) optionally includes an inert gas input port (1100). An inert gas line extending from a gas supply module, not shown, is connected to the inert gas port (1100) and delivers a flow of inert gas (1105) to the inert gas port (1100). The flow of inert gas (1105) is preferably pressure regulated to about 40 PSI. The flow of inert gas (1105) passes through the inert gas input port (1100) and enters the precursor vapor delivery line (1050) through the ALD pulse valve (1095) and flows in only one direction toward the reaction chamber (1010), through the ALD manifold (1055).

In a first non-limiting example embodiment, the inert gas (1105) flows continuously through the ALD pulse valve (1095) delivering a substantially constant mass flow rate of inert gas into the reaction chamber (1010) through the ALD manifold (1055). In a second non-limiting example embodiment, the ALD pulse valve (1095) modulates inert gas (1105) flowing through the ALD pulse valve (1095) using the same solenoid actuated movable gate of the ALD pulse valve (1095) used to modulate precursor vapor flow to the reaction chamber. In particular when the single solenoid actuated movable gate of the ALD pulse valve (1095) is closed neither the precursor vapor in the precursor container nor the inert gas (1105) received through the port (1105) can flow through the ALD pulse valve (1095). However when the single solenoid actuated movable gate of the ALD pulse valve (1095) is opened both the precursor vapor and the inert gas flow can flow through the ALD pulse valve (1095) during the pulse duration. In a third non-limiting example embodiment, the ALD pulse valve (1095) is configured to separately modulate inert gas (1105) and precursor vapor flowing through the ALD pulse valve (1095). This is accomplished using the two solenoid actuated movable gates with a first movable gait operable to modulate precursor vapor flow to the reaction chamber and a second movable gait operable to modulate inert gas flow. Thus one of the two solenoid actuated movable gates of the ALD pulse valve (1095) is opened and closed to module precursor vapor flow to the reaction chamber (1010) and the other of the two the two solenoid actuated movable gates of the ALD pulse valve (1095) is opened and closed to module precursor flow to the reaction chamber (1010). In a further alternate embodiment, inert gas (1105) is not introduced into the ALD pulse valve (1095) but instead is delivered into elements of the ALD manifold (1055) which are configured to deliver inert gas into reaction chamber (1055) and or to mix inert gas with precursor vapor inside the ALD manifold (1055). Thus a two port ALD pulse valve (1095), like the flow inert gas flow valve (1080) is usable without deviating from the present invention.

During normal operation manual valves (1), (3) and (4) are open and the manual valve (2) is closed. The ALD pulse valve (1095) and the controllable inert gas flow valve (1080) are initially closed. In a preferred embodiment, a steady flow of inert gas (1105) flows through the ALD pulse valve (1095) to the reaction chamber (1010) through the ALD manifold (1055). As noted above the precursor container (1025) contains a low vapor pressure liquid or solid precursor material (1030) partially filled up to a fill level (1035) and the inert gas input line (1045) is configured to inject inert gas into the precursor container (1025) below the fill level (1035) such that inert gas injected into the precursor container (1025) promotes entrainment of liquid or solid precursor in the inert gas flow as the inert gas bubbles through the liquid or solid precursor (1030) to the vapor space (1040).

In one non-limiting exemplary operating mode both the ALD pulse valve (1095) and the flow valve (1080) are opened simultaneously each with the same pulse duration. Thus the inert gas flow valve (1080) injects a pulse volume of inert gas into the precursor container (1025) synchronously with the release a pulse volume of precursor vapor from the precursor container (1025) into the reaction chamber through the ALD pulse valve (1095). In other operating modes the controllable inert gas flow valve (1080) may have a longer pulse duration than the pulse duration of the ALD pulse valve (1095). Thus in one example operating mode embodiment the controllable inert gas flow valve (1080) is operated to open before the ALD pulse valve (1095) is opened and close after the ALD pulse valve has closed with the result that inert gas is bubbled through the liquid or solid precursor during the entire duration of each pulse of the ALD pulse valve (1095). Also as described above, a plurality of precursor pulse volumes can be injected into the precursor container for each precursor vapor pulse volume injected into the reaction chamber by pulsing controllable inert gas flow valve (1080) a plurality of times for each pulse of the ALD pulse valve (1095).

Each time the controllable inert gas flow valve (1080) opens, inert gas present in the inert gas input line (1045), which has a substantially fixed input gas pressure, overcomes the threshold pressure of the check valve (1070) and flows through the flow restrictor (1070) and through the controllable inert gas flow valve (1080) into the precursor container (1025). Since the ALD pulse valve (1095) and the controllable inert gas flow valve (1080) are both open for at least a portion of the pulse duration of the ALD pulse valve (1095), precursor vapor from the vapor space (1040) flows uninterrupted into the reaction chamber (1010) during the entire ALD pulse duration, and inert gas from the inert gas input line (1045) flow flows uninterrupted into the precursor container (1025) below the fill level (1035) during the entire flow valve pulse duration. Moreover since the input gas (1060) is at a substantially fixed gas pressure and its mass flow rate is substantially limited by the flow restrictor (1075), a substantially uniform volume of inert gas equal to the inert gas pulse volume is delivered into the precursor container (1025) during each pulse duration of the controllable inert gas flow valve (1080). After the pulse duration of the ALD pulse valve (1095) and corresponding pulse duration of the controllable inert gas flow valve (1080) both valves are closed and the check valve (1070) also closes trapping a volume of inert gas in the input line (1045) between the check valve (1070) and the controllable inert gas flow valve (1080). Since the vacuum chamber is at a vacuum pressure and the inert gas input is at 40 PSI there is very little likelihood that any precursor vapor escapes from the precursor container through the input line as long as the vacuum pump is operating.

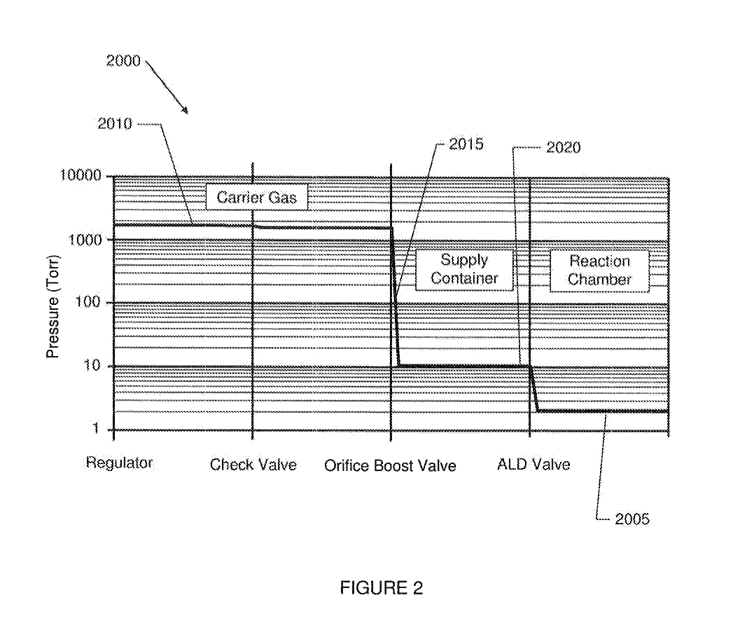

Referring now to FIG. 2, a gas pressure vs system location plot (2000) depicts gas pressure in Torr at various locations of the ALD system (1000) shown in FIG. 1. Starting from the inert gas input (1060), an inert gas supply is delivered from a gas supply module at about 40 psig or about 2070 Torr. In the reaction chamber (1010) the vacuum pump (1020) operates continuously to pump the reaction chamber down to 1 Torr or less (2005).

The gas pressure regulator (1065) is set to regulate input gas pressure at 1000 Torr (2010) which is labeled carrier gas in FIG. 2. The 1000 Torr pressure (2010) is substantially constant along the inert gas input line (1045) up to the position of the flow restrictor (1075), labeled orifice boost valve in FIG. 2. The flow restrictor (1075) cases a pressure gradient (2015) which drops gas pressure from 1000 Torr to 10 Torr. Thus the total gas pressure inside the precursor container (1025), labeled supply container in FIG. 2, and in the precursor vapor line (1050) leading up to the ALD pulse valve (1095) is about 10 Torr (2020). The pressure gradient across the ALD pulse valve (2025) drops gas pressure from 10 Torr to 1 Torr or less.

The pressure values depicted in FIG. 2 are not constant pressure values but merely represent a non-limiting example of a preferred pressure model showing average pressure values over time for a particular input gas pressure of a 1000 Torr and for a particular reaction chamber gas pressure. It is noted that with the ALD pulse valve (1095) closed the vacuum pump (1020) operates to reduce gas pressure inside the reaction chamber (1010) to about 0.3 to 0.5 Torr but lower pressures are not outside the scope of the present invention. It will be recognized that gas pressure inside the vacuum chamber (1010) increases in response to each precursor pulse volume injected into the reaction chamber by an ALD pulse duration and that increasing pules volume further increases gas pressure inside the reaction chamber. Similarly gas pressure inside the precursor container (1025) fluctuates in response to each precursor pulse volume drawn from the vapor space (1040) and each inert gas pulse being injected into the precursor container (1025) by an inert gas flow valve pulse. It will also be recognized that the average gas pressure inside the reaction chamber (1010) is further influenced by the inert gas flow (1105) that enters the ALD valve input port (1100). When the gas flow (1105) is continuous, the average gas pressure in reaction chamber may be increased and the mass flow rate of the inert gas flow (1105) can be adjusted to vary the average gas pressure in reaction chamber as needed. It is further noted that while only one precursor container (1025) is described herein, the ALD system (1000) utilizes at least two precursors for each ALD cycle and a second precursor delivery system, not shown, is included in the ALD system (1000) and it will be recognized that that operation of the second precursor delivery system also affects average gas pressure in reaction chamber.

A second precursor delivery system includes a second precursor container interfaced with the ALD manifold (1055) and operating to deliver a second precursor into the reaction chamber (1010) independently of the first precursor being delivered from the precursor container (1025). While in some embodiments the second precursor delivery system may be substantially identical to the elements of the precursor delivery elements described herein and shown in FIG. 1, various other second precursor delivery mechanisms are usable. Moreover in a preferred embodiment more than two precursor delivery systems are interfaced with the ALD manifold (1055) and controlled by the system controller (1085) such that he ALD system (1000) is operable to selected different precursor combinations as need to preform different ALD coating cycle types.

According to the present invention further aspects of the inert gas mass flow rate into the precursor container (1025) are described below. In one aspect a large pressure gradient across the flow restrictor (1075), shown as (2015) in FIG. 2, is desirable to prevent back flow from the precursor container (1025) toward the inert gas input (1060). In a second aspect two different desirable mass flow rate examples are provided for two different orifice sizes of the flow restrictor (1075).

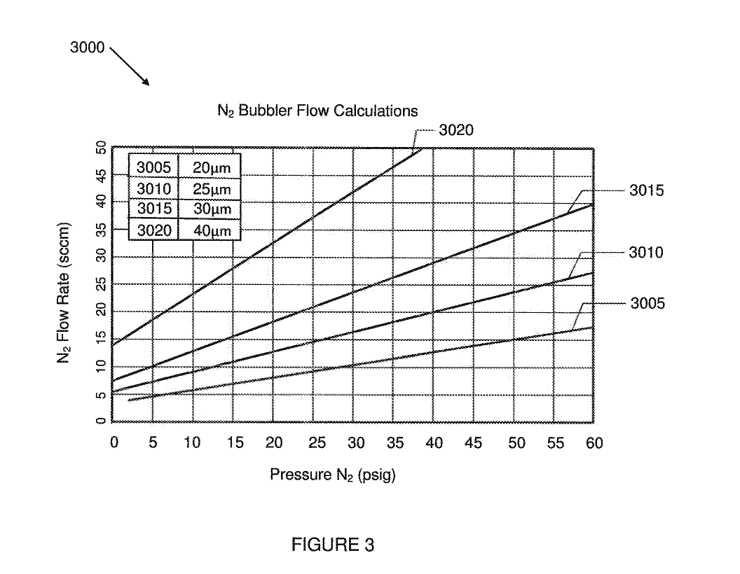

Referring to FIG. 3 a plot (3000) shows inert gas flow rate in standard centimeters per minute (sccm) vs input gas pressure in pounds per square inch gauge (psig), for four different flow restrictor orifice diameters in microns (μm). In this case gas pressure is the gas pressure set by the pressure regulator (1065) upstream of the flow restrictor (1075) shown in FIG. 1. As can be seen in curve (3005) associated with a 20 μm diameter orifice for a gas pressure range of 5 to 60 psig, the 20 μm diameter orifice provides gas flow rates across the orifice in the range of 5 to 18 sccm. The curves (3010), (3015) and (3020) associated with a 25 μm diameter orifice, a 30 μm diameter orifice and a 40 μm diameter orifice each show respective gas flow rates vs gas pressure results.

Referring now to TABLE 1, gas pressure at various locations in the ALD system (1000) is shown for the case where the flow restrictor (1075) of FIG. 1 has a 50 μm orifice diameter and wherein the pressure regulator (1065) shown in FIG. 1 is set at 15 psig in a first instance and −10 in Hg in a second instance. A factor in selecting system operating parameters is the desire to provide a large enough pressure gradient across the flow restrictor (1075) and inert gas flow valve (1080) to prevent precursor vapor back flow into the inert gas input line (1045) and avoid the risk of air leaking into the inert gas input line (1045).

TABLE 1 lists various locations of the ALD system (1000) and shows gas pressure, pressure gradient and mass flow rates at the various locations for two different gas regulator pressure settings. As detailed above, gas pressure in the reaction chamber (1010), ALD manifold (1055) is largely governed by operation of the vacuum pump and somewhat independent of the gas pressure dynamics of in the inert gas input line (1045). Similarly the volume between the controllable inert gas flow valve (1080) and the ALD pulse valve (1095), which includes the precursor container (1025), is somewhat isolated from gas dynamics in the inert gas input line (1045) and somewhat isolated from gas dynamics in the ALD manifold and reaction chamber, except when both valves are opened during pulse durations. However since the pule durations are less than 100 msec and the flow restrictor (1075) restricts mass flow rate into the precursor container (1025) the present invention effectively preserves a substantially constant or acceptably variable gas pressure in the precursor container (1025) by isolating the precursor container from the input gas flow and gas removal from the reaction chamber while at the same time injecting controlled pulses of inert gas into the precursor container as precursor vapor pulse are removed.

As shown in TABLE 1 the combination of a 50 μm diameter orifice in the flow restrictor (1075) with an input gas pressure of 1535 Torr (15 psig), set by the pressure regulator (1065) provides a pressure gradient across the flow restrictor and inert gas flow valve (1080) of 1430 Torr when the valve (1080) is open, i.e. during pulse durations. At the same time the mass flow rate through the open valve (1080) is about 55 sccm. Applicants have found that a pressure gradient of >760 Torr is desirable to prevent precursor vapor back flow into the inert gas input line (1045) and to avoid the risk of air leaking into the inert gas input line (1045).

Meanwhile the TABLE 1 also shows the combination of a 50 μm diameter orifice in the flow restrictor (1075) with an input gas pressure of 500 Torr (15 psig), set by the pressure regulator (1065) provides a pressure gradient across the flow restrictor and inert gas flow valve (1080) of 450 Torr when the valve (1080) is open, i.e. during pulse durations. At the same time the mass flow rate through the open valve (1080) is about 20 sccm.

Based on the preferred operating mode wherein the input gas pressure is 1535 Torr (15 psig) and the mass flow rate through the open valve (1080) is 55 sccm and the pulse duration of the inert gas flow valve (1080) is 100 msec, the pulse volume generated is 0.092 cubic centimeters.

To exchange the precursor containers (1025) or otherwise purge the vapor space (1040) and the inert gas input line (1045) valve (1) is closed, valve (2) is opened and valve (3) remains open while the ADL pulse valve (1095) is either pulsed several times or opened long enough to purge the precursor vapor space (1040) and the inert gas input liner (1045). There after the valve (4) is closed and valve (30 is closed and the precursor container (1025) is removed by disconnecting at the quick connect fittings (1057).

In further embodiments the inert gas input line (1045) can enter the precursor container (1025) through any surface, top, bottom or sides, as long as the inert gas is injected below the fill line (1035). It will be recognized that the fill liner (1035) moves as the precursor supply is replenished and subsequently replaced. Any of the manual valves (1, 2, 3, 4) may comprise controllable actuator valves controlled by the electronic controller (1085). The gas pressure regulator (1065) may be manually set to a desired pressure by an operator or during a calibration or comprise a controllable device controlled by the electronic controller (1085).

The system (1000) may include one or more gas pressure sensors (1115) in communication with the system controller (1085) to sense gas pressure one or more areas of the ALD system (1000), such as between as may be advantageous to operate and or evaluate ALD deposition cycles.

The present invention eliminates the need for a carrier gas (bypass) flow path to channel input gas out of the system when the flow valve is closed.

The present invention allows accurate control of the carrier gas flow rate (sccm) by using a controlled pressure and flow restrictor arrangement.

TABLE 1

| | Pressure regulator set | | Pressure regulator set | | |
|---|---|---|---|---|---|
| Location | at 30 psig | | at 10 psig | | Comment |
| Pressure at input to | 2069 | Torr (40 psig) | 2069 | Torr (40 psig) | Input pressure at (1060) |
| pressure regulator | | | | | FIG. 1 |
| Pressure at output | 1535 | Torr (15 psig) | 500 | Torr (−10 in Hg) | Pressure setting of |
| from pressure | | | | | (1065) FIG. 1 |
| regulator | | | | | |
| Mass flow rate across | 55 | sccm | 20 | sccm | 50 μm orifice |
| flow restrictor (1075) | | | | | |
| FIG. 1 | | | | | |
| Pressure at output of | 1480 | Torr | 450 | Torr | Based on 1 psi cracking |
| check valve (1070) | | | | | pressure |
| FIG. 1 | | | | | |
| Pressure gradient | 1403 | Torr | 400 | Torr | Preferably >760 Torr |
| across flow restrictor | | | | | (15 psig) to avoid back |
| (1070) FIG. 1 | | | | | flow |
| Vapor pressure inside | <10 | Torr | <10 | Torr | <1 Torr for very low |
| precursor container | | | | | vapor pressure |
| (1025) FIG. 1 | | | | | precursors |
| Pressure at ALD | 2-6 | Torr | 2-6 | Torr | |
| manifold (1055) FIG. 1 | | | | | |
| Pressure at reaction | 0.3-0.5 | Torr | 1.3-0.5 | Torr | |
| chamber (1010) FIG. 1 | | | | | |

1. An ALD system comprising:
a reaction chamber connected to a vacuum pump operable to remove gas from the reaction chamber;
a precursor container containing one of a liquid and a solid precursor material filled to a fill level wherein a vapor space is formed above the fill level;
an inert gas input line provided to receive inert gas from an inert gas source and deliver the inert gas into the precursor container below the fill level;
a precursor vapor line disposed between the precursor vapor space and the reaction chamber;
a controllable ALD pulse valve disposed along the precursor vapor line between the precursor vapor space and the reaction chamber;
a controllable inert gas flow valve disposed along the inert gas input line between the precursor container and the inert gas source;
system controller in electrical communication with each of the controllable ALD pulse valve and the controllable inert gas flow valve operable to pulse each of the controllable ALD pulse valve and the controllable inert gas flow valve to and open position to thereby simultaneously inject a pulse volume of inert gas into the precursor container below the fill level and inject a pulse volume of precursor vapor into the reaction chamber, wherein the pulse volume of precursor vapor is delivered from the vapor space.

2. The vapor delivery system of claim 1 further comprising a flow restrictor disposed along the inert gas input line between the controllable inert gas flow valve and the inert gas source.

3. The vapor delivery system of claim 2 further comprising a gas pressure regulator disposed along the inert gas input line between the flow restrictor and the inert gas source.

4. The vapor delivery system of claim 3 further comprising a check valve disposed along the inert gas input line between the flow restrictor and the inert gas source wherein the check valve prevents gas from flowing through the check valve is the direction of the inert gas source.

5. The vapor delivery system of claim 3 wherein the gas pressure regulator is set to regulate gas pressure in the inert gas input line wherein the gas is regulated to a pressure in the range of 1 to 60 psig and wherein the flow restrictor comprises a circular orifice have a diameter in the range of 20 to 100 μm.

6. The vapor delivery system of claim 1 wherein each of the controllable ALD pulse valve and the controllable inert gas flow valve is operable to a pulse open and close with a pulse duration range of 1 to 100 msec.

7. The vapor delivery system of claim 1 wherein during ALD cycles an average gas pressure in the reaction chamber is maintained at less than 1 Torr, an average gas pressure in the precursor container is maintained at greater than the average gas pressure in the reaction chamber in a range of less than 1 Torr to 10 Torr.

8. The vapor delivery system of claim 5 wherein during ALD cycles an average gas pressure in the reaction chamber is maintained at less than 1 Torr, an average gas pressure in the precursor container is maintained at greater than the average gas pressure in the reaction chamber and less than 1 Torr and the gas pressure regulator is set to provide an average input gas pressure in the range 500 to 2000 Torr.

9. The vapor delivery system of claim 2 wherein the flow restrictor is configured to provide a pressure gradient of at least 760 Torr between the inert gas supply and the precursor container.

10. The vapor delivery system of claim 2 wherein the flow restrictor is configured to provide a mass flow rate of inert gas passing there through in the range of 20 to 100 sccm during pulse durations of the controllable inert gas flow valve.

11. The vapor delivery system of claim 1 wherein the ALD pulse valve includes an inert gas port for receiving inert gas from an inert gas supply delivering the inert gas received therein into the reaction chamber through the precursor vapor line.

12. A method comprising:
removing gas from a reaction chamber with an operating vacuum pump;
providing a precursor container containing one of a liquid and a solid precursor material filled to a fill level wherein a vapor space is formed above the fill level;
receiving inert gas intro an inert gas input line from an inert gas source and delivering the inert gas into the precursor container below the fill level;
providing a precursor vapor line disposed between the precursor vapor space and the reaction chamber;
operating a controllable ALD pulse valve disposed along the precursor vapor line between the precursor vapor space and the reaction chamber;
operating a controllable inert gas flow valve disposed along the inert gas input line between the precursor container and the inert gas source;
operating a system controller in electrical communication with each of the controllable ALD pulse valve and the controllable inert gas flow valve to open the controllable ALD pulse valve for an ALD pulse duration and to open the controllable inert gas flow valve for a flow pulse duration wherein at least a portion of the ALD pulse duration and the flow pulse duration is overlapping.

13. The method of claim 12 wherein the ALD pulse duration and the flow pulse duration start and end simultaneously.

14. The method of claim 13 wherein the ALD pulse duration and the flow pulse duration have a temporal range of 1 to 100 msec.

15. The method of claim 12 wherein the ALD pulse duration is shorter than the flow pulse duration.

16. The method of claim 12 wherein the ALD pulse duration is longer than the flow pulse duration.

17. The method claim 12 further comprising:
providing a flow restrictor disposed along inert gas input line between the inert gas source and the controllable inert gas flow valve;
providing a gas pressure regulator disposed along inert gas input line between the inert gas source and the flow restrictor;
wherein the gas pressure regulator and the flow restrictor are configured to provide a pressure gradient of at least 760 Torr between the inert gas supply and the precursor container.
